(19) United States
(12) Patent Application Publication
(10) Pub. No.: US 2026/0344306 A1
(43) Pub. Date: Oct. 29, 2026

(54) SEMICONDUCTOR DEVICE INCLUDING RESISTANCE CHANGE CHANNEL LAYER HAVING NANODOTS AND METHOD OF MANUFACTURING THE SAME

(71) Applicant: SK hynix Inc., Icheon-si (KR)

(72) Inventor: Hwan Young KIM, Icheon-si (KR)

(21) Appl. No.: 19/322,161

(22) Filed: Sep. 8, 2025

(30) Foreign Application Priority Data
Apr. 28, 2025 (KR) 10-2025-0055678

(51) Int. Cl. H10N 70/00; H10B 63/00; H10N 70/20

(52) U.S. Cl. CPC H10N 70/828; H10B 63/00; H10N 70/021; H10N 70/023; H10N 70/026; H10N 70/24; H10N 70/253; H10N 70/8833; H10N 70/8836

(57) ABSTRACT

A semiconductor device includes a substrate, a resistance change channel layer disposed over the substrate and including oxygen vacancies, nanodots disposed in the resistance change channel layer, a source electrode layer and a drain electrode layer disposed respectively at opposite ends of the resistance change channel layer, an oxygen vacancy reservoir layer disposed on the resistance change channel layer and configured to exchange the oxygen vacancies with the resistance change channel layer, and a gate electrode layer disposed on the oxygen vacancy reservoir layer.

### CROSS-REFERENCE TO RELATED APPLICATIONS

The present application claims priority under 35 U.S.C §119(a) to Korean Application No. 10-2025-0055678, filed in the Korean Intellectual Property Office on Apr. 28, 2025, the entire contents of which are incorporated herein by reference.

### BACKGROUND

### 1. Technical Field

The present disclosure generally relates to semiconductor devices having resistance change characteristics.

### 2. Related Art

Recently, electrochemical random access memory (hereinafter, referred to “ECRAM”) devices have been proposed. ECRAM refers to a memory technology in which information is stored by utilizing an electrochemical reaction. The ECRAM devices are distinguished from conventional flash memory devices, ferroelectric memory devices, or magnetic memory devices in that the ECRAM devices operate based on modulation of the ion state within a material.

For example, in a field effect transistor(FET)-type ECRAM device with a metal oxide channel layer, the electrical resistance of the metal oxide channel layer depends on a concentration of oxygen vacancies distributed inside the metal oxide channel layer. Due to unique operation characteristics resulting from the modulation of the ion state, ECRAM devices are attracting industry attention as a memory device capable of realizing high energy efficiency.

### SUMMARY

The present disclosure provides a memory device that may include a substrate, a resistance change channel layer disposed over the substrate and including oxygen vacancies, nanodots disposed in the resistance change channel layer, a source electrode layer and a drain electrode layer disposed respectively at opposite ends of the resistance change channel layer, an oxygen vacancy reservoir layer disposed on the resistance change channel layer and configured to exchange oxygen vacancies with the resistance change channel layer, and a gate electrode layer disposed on the oxygen vacancy reservoir layer.

The present disclosure provides a memory device that may include a substrate, a resistance change channel layer disposed over the substrate to extend in a first direction perpendicular to a surface of the substrate and including oxygen vacancies, a plurality of nanodots to form a plurality of rows disposed in the resistance change channel layer in a thickness direction of the resistance change channel layer, a source electrode layer and a drain electrode layer disposed respectively at opposite ends of the resistance change channel layer, an oxygen vacancy reservoir layer disposed adjacent to the resistance change channel layer in a second direction perpendicular to the first direction, and a gate electrode layer disposed adjacent to the oxygen vacancy reservoir layer in the second direction.

There is disclosed a method of manufacturing a semiconductor device. In the method, a source electrode layer and a drain electrode layer that are disposed to be spaced apart from each other may be formed on one surface over a substrate. A resistance change channel layer including nanodots may be formed between the source electrode layer and the drain electrode layer on the one surface over the substrate. An oxygen vacancy reservoir layer may be formed on the resistance change channel layer. A gate electrode layer may be formed on the oxygen vacancy reservoir layer.

### BRIEF DESCRIPTION OF THE DRAWINGS

FIG. 1 schematically illustrates a semiconductor device according to an embodiment of the present disclosure.

FIGS. 2A-2E schematically illustrate a write operation of a semiconductor device according to an embodiment of the present disclosure.

FIG. 3 schematically illustrates a semiconductor device according to an embodiment of the present disclosure.

FIG. 4 is a flow chart schematically illustrating a method of manufacturing a semiconductor device according to an embodiment of the present disclosure.

FIGS. 5-10 are cross-sectional views schematically illustrating a method of manufacturing a semiconductor device according to an embodiment of the present disclosure.

FIGS. 11 and 12 schematically illustrate a method of manufacturing a semiconductor device according to an embodiment of the present disclosure.

FIG. 13 is a cross-sectional view schematically illustrating a semiconductor device according to an embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Terms used in the specification of the present application are terms selected in consideration of functions in the presented embodiments, and the meaning of the terms may vary depending on the intention or custom of a user or operator in the technical field. The meanings of the terms used follow the definitions defined when specifically defined herein, and may be interpreted as meanings generally recognized by those skilled in the art in the absence of specific definitions.

In the present specification, a write operation of a semiconductor device includes a first write operation and a second write operation. The first write operation means an operation of increasing a conductance value of a resistance change channel layer of the semiconductor device (or an operation of reducing electrical resistance). The resistance change channel layer maintains the increased conductance value even after the first write operation is completed. Accordingly, the semiconductor device can non-volatilely store signal information corresponding to the increased conductance value. The second write operation means an operation of reducing the conductance value (or increasing the electrical resistance) of the resistance change channel layer. The resistance change channel layer maintains the reduced conductance value even after the second write operation is completed. Accordingly, the semiconductor device can store the signal information in a non-volatile manner corresponding to the reduced conductance value.

In the present specification, a read operation of a semiconductor device means an operation of measuring the conductance value of the resistance change channel layer by applying a voltage to opposite ends of the resistance change channel layer. As a result, the signal information stored in the semiconductor device by the first and second write operations can be read.

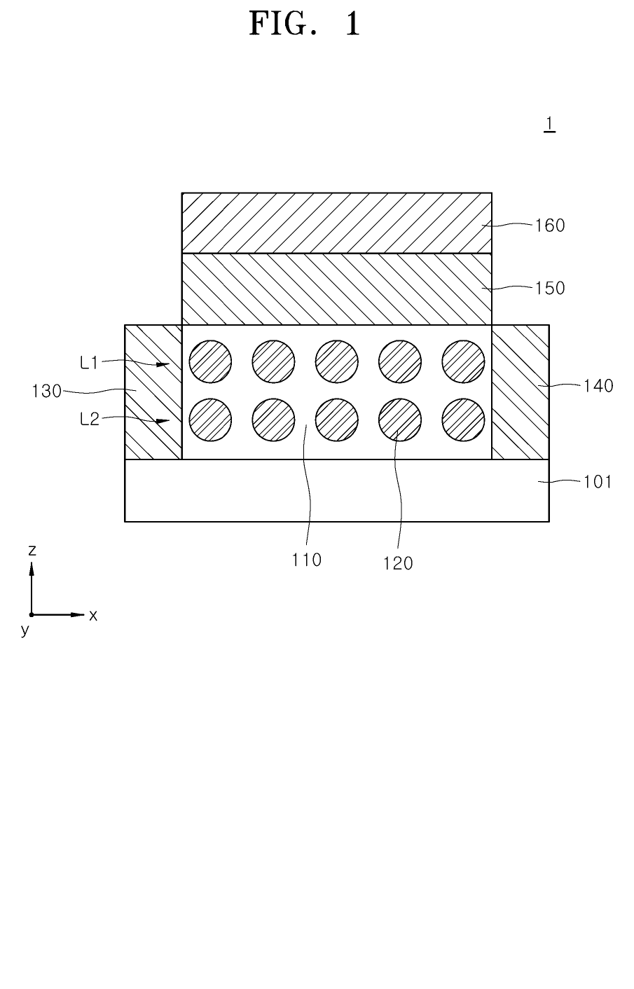

FIG. 1 schematically illustrates a semiconductor device according to an embodiment of the present disclosure.

Referring to FIG. 1, a semiconductor device 1 includes a substrate 101, a resistance change channel layer 110 disposed on the substrate 101, nanodots 120 disposed within the resistance change channel layer 110, a source electrode layer 130 and a drain electrode layer 140 disposed respectively at opposite ends of the resistance change channel layer 110, an oxygen vacancy reservoir layer 150 disposed on the resistance change channel layer 110, and a gate electrode layer 160 disposed on the oxygen vacancy reservoir layer 150.

The substrate 101 includes various materials to which a semiconductor integration process is applicable. In an embodiment, the substrate 101 may include a semiconductor material. The semiconductor material may include, for example, silicon (Si), germanium (Ge), gallium arsenide (GaAs), molybdenum selenide (MoSe₂), hafnium selenide (HfSe₂), indium selenide (InSe), gallium selenide (GaSe), black phosphorous, indium-gallium-zinc oxide (IGZO), or a combination of two or more thereof. The substrate 101 may be doped with an N-type or P-type dopant to have electrical conductivity.

The resistance change channel layer 110 is disposed on the substrate 101. The resistance change channel layer 110 includes oxygen vacancies of various concentrations. The oxygen vacancies may be generated in the resistance change channel layer 110 when the resistance change channel layer 110 is formed by a semiconductor integration process. Alternatively, the oxygen vacancies may be generated in the resistance change channel layer 110 during a write operation of the semiconductor device 1 described below. The resistance change channel layer 110 may have a conductance value that changes according to the concentration of the oxygen vacancies. Oxygen vacancies may function as a dopant that provides electrons, which are conductive carriers, within the resistance change channel layer 110. Accordingly, the conductance value of the resistance change channel layer 110 may increase as the concentration of the oxygen vacancy is increases.

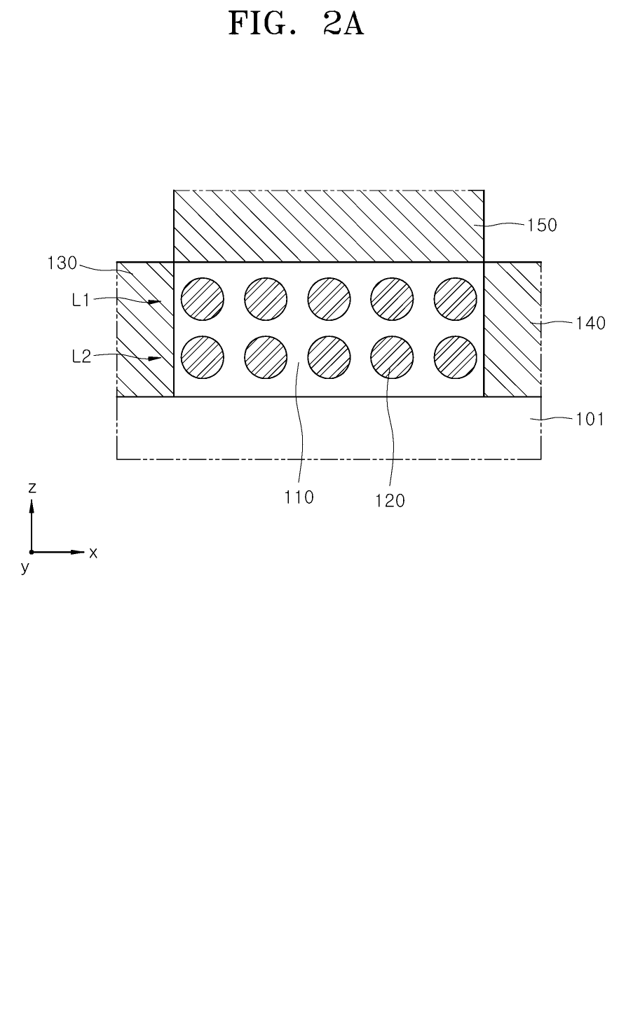

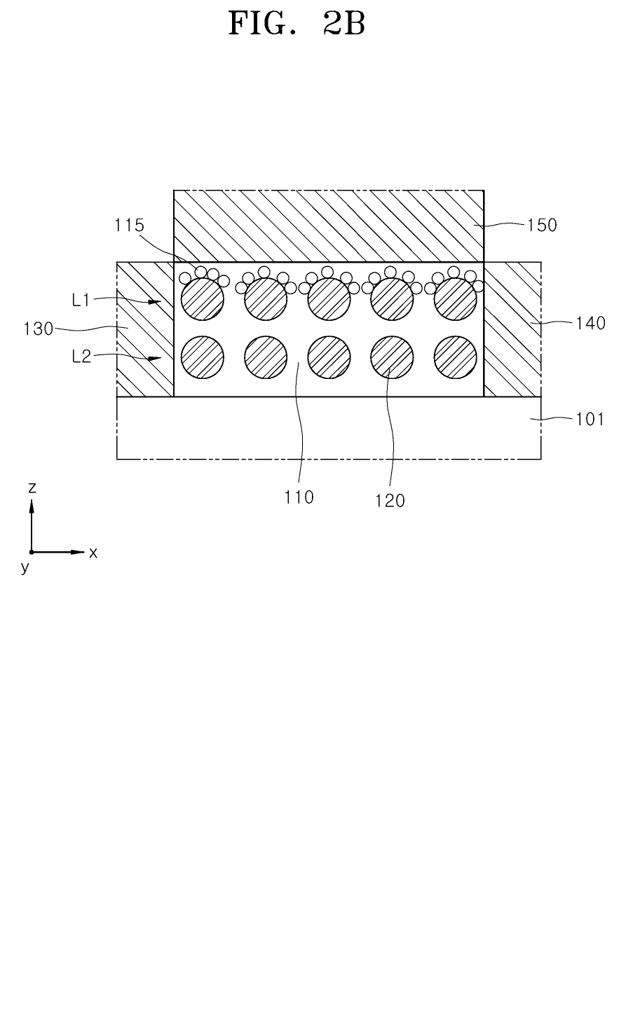

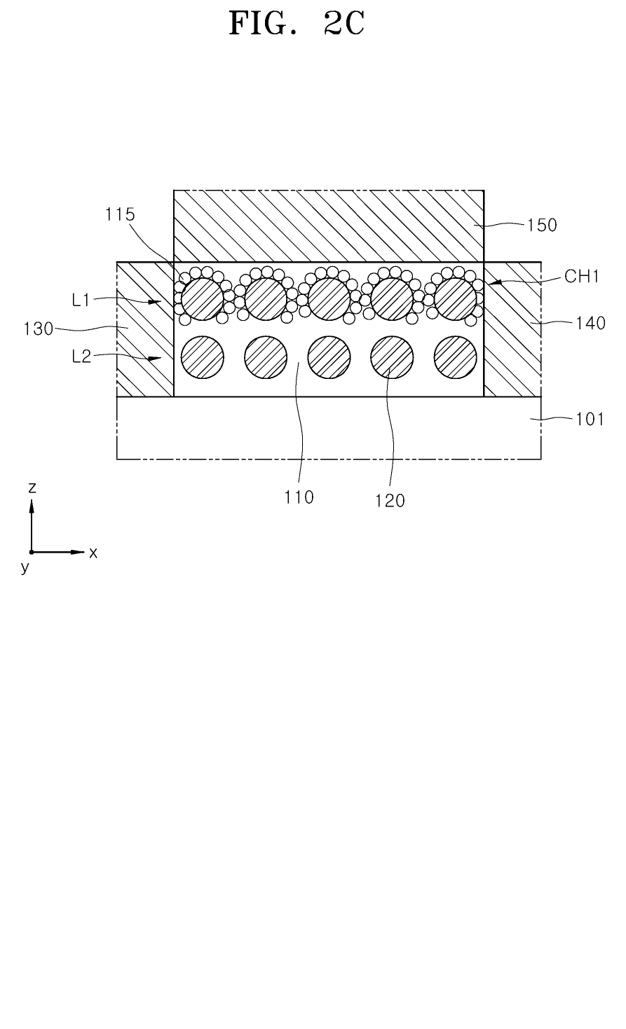

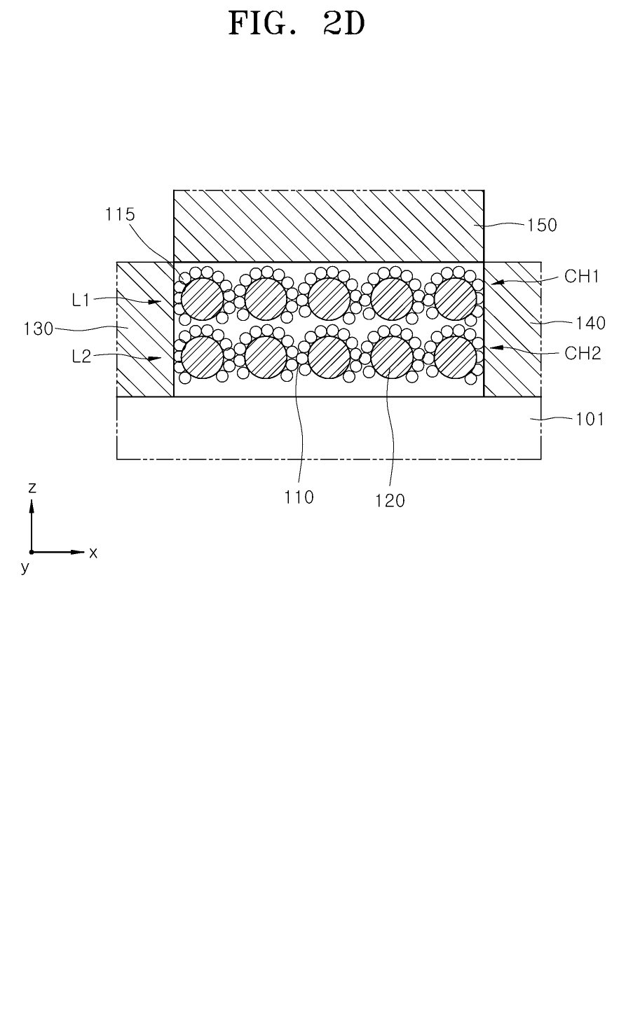

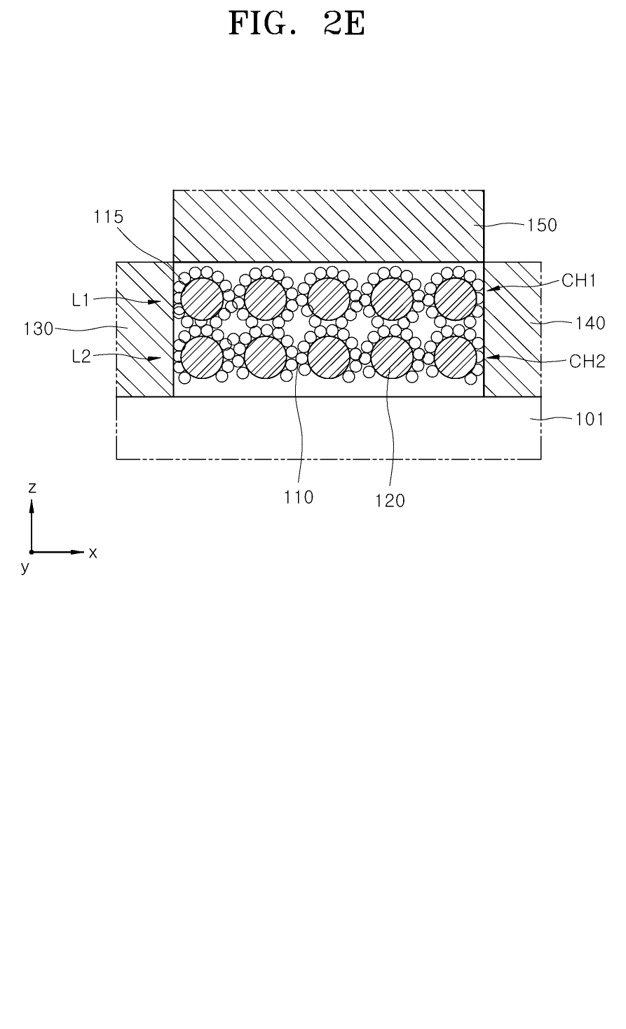

In an embodiment, a write operation may be performed by changing the conductance value of the resistance change channel layer 110 by controlling the concentration and distribution of the oxygen vacancies in the resistance change channel layer 110. Specifically, as described below with reference to FIGS. 2A-2E, to the write operation may be performed by applying a write voltage between the gate electrode layer 160 and the substrate 101. The resistance change channel layer 110 may exchange oxygen vacancies (or oxygen ions) with the oxygen vacancy reservoir layer 150. The conductance value of the resistance change channel layer 110 may be determined depending on the concentration and distribution state of the oxygen vacancies remaining in the resistance change channel layer 110 after the write voltage is removed. The resistance change channel layer 110 may have a plurality of resistance states that are distinguishable from each other depending on the magnitude of the conductance value.

In an embodiment, the resistance change channel layer 110 includes meal oxide containing the oxygen vacancies. In other words, the metal oxide may have an insufficient content of oxygen bound to the metal in terms of the stoichiometric ratio. The metal oxide may include, for example, tungsten oxide, titanium oxide, molybdenum oxide, selenium oxide, iron oxide, cobalt oxide, vanadium oxide, strontium titanium oxide, yttrium oxide, indium gallium zinc oxide, yttria-stabilized zirconia (ZrO₂-Y₂O₃), hafnium yttria (HfO₂-Y₂O₃), gadolinium-doped ceria (CeO₂-Gd₂O₃), lanium strontium manganese oxide, lanium strontium cobalt oxide, or a combination of two or more thereof. The resistance change channel layer 110 may have a thickness of, for example, 10 nm to 30 nm.

Referring to FIG. 1, the nanodots 120 are disposed within the resistance change channel layer 110. A nanodot 120 may be an island-type material pattern having a size in the order of nanometers, or “nano-size.” The nanodots 120 include particles aggregated in a nano-size. For example, a nano-size may mean that at least one dimension such as diameter, length, width, and height of the particle ranges from 1 nm to 10 nm. The nanodot 120 may have a shape such as a sphere, an ellipsoid, a cylindrical pillar or rod, and a rectilinear pillar. When the nanodot 120 has a spherical shape, the nanodot 120 may have a diameter of 1 nm to 10 nm, for example. The nanodot 120 may include, for example, gold (Au), silver (Ag), copper (Cu), palladium (Pd), platinum (Pt), nickel (Ni), zinc oxide, titanium oxide, tin oxide, iron oxide, copper oxide, aluminum oxide, cadmium sulfide (CdS), cadmium selenide (CdSe), cadmium telluride (CdTe), lead sulfide (PbS), lead selenide (PbSe), lead telluride (PbTe), tin sulfide (SnS), tin selenide (SnSe), graphene oxide, lead cesium chloride (CsPbCl₃), lead cesium bromide (CsPbBr₃), silver cesium chloride (CsAgCl₂), silver cesium bromide (CsAgBr₂), or a combination of two or more thereof.

In an embodiment, the nanodots 120 are uniformly distributed within the resistance change channel layer 110. For example, the nanodots 120 may be disposed in a thickness direction, that is, a z-direction, of the resistance change channel layer 110 to form a plurality of rows arranged along the z-direction. In FIG. 1, the nanodots 120 are arranged in two rows, that is, the first row L1 and the second row L2, but embodiments are not necessarily limited thereto. In other embodiments, the nanodots may be arranged to form one row, three or more rows. As another example, the nanodots 120 may be disposed along a longitudinal direction of the resistance change channel layer 110, that is, an x-direction. The nanodots 120 may be disposed along the x-direction in a region of the resistance change channel layer 110, from the adjacent source electrode layer 130 to a region adjacent to the drain electrode layer 140.

In an embodiment, the nanodots 120 may restrain the oxygen vacancies through interaction with the oxygen vacancies in the resistance change channel layer 110. According to one of various scientific models that describe the interaction between nanodots and oxygen vacancies, when the nanodots include metal or a doped semiconductor, the nanodots may be charged with a negative charge under an externally applied electric field. Because the oxygen vacancies have positive charges, the nanodots attract the oxygen vacancies through electrostatic attraction and restrain the oxygen vacancies around the nanodots. According to another of the various scientific models, when a nanodot has an energy level lower than that of the oxygen vacancy, electrons may move from the oxygen vacancies to the nanodots. The oxygen vacancies that lose electrons may be restrained around the nanodots. According to another of the various scientific models, when a nanodot includes metal such as gold (Au) or platinum (Pt), the nanodot may form chemical bonds with oxygen vacancies at an interface with the metal oxide of the resistance change channel layer. Through chemical bonds, the oxygen vacancies may be restrained by the nanodots.

Referring to FIG. 1, the source electrode layer 130 and the drain electrode layer 140 are disposed spaced apart from each other on the substrate 101. Each of the source electrode layer 130 and the drain electrode layer 140 includes a conductive material. The conductive material may include, for example, doped semiconductor, metal, conductive metal nitride, conductive metal carbide, conductive metal silicide, or conductive metal oxide. The conductive material may include, for example, silicon (Si) doped with an n-type dopant or a p-type dopant, tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium silicide, titanium silicide, tantalum silicide, tantalum silicide, ruthenium oxide, or a combination of two or more thereof.

The oxygen vacancy reservoir layer 150 is disposed on the resistance change channel layer 110. The oxygen vacancy reservoir layer 150 includes metal oxide containing oxygen vacancies. That is, the metal oxide may have an insufficient content of oxygen bonded to the metal in terms of the stoichiometric ratio. The metal oxide may include, for example, gadolinium oxide, molybdenum oxide, tungsten oxide, copper oxide, titanium oxide, cerium oxide, yttria-stabilized zirconia (ZrO₂-Y₂O₃), gadolinium-doped ceria (CeO₂-Gd₂O₃), scandia-stabilized zirconia (ScSZ), lanthanum strontium cobalt oxide, barium strontium cobalt iron oxide, praseodymium nickel oxide, neodymium nickel oxide, lanthanum nickel oxide, or a combination of two or more thereof.

The oxygen vacancy reservoir layer 150 is configured to exchange the oxygen vacancies (or oxygen ions) with the resistance change channel layer 110, depending on a voltage applied between the gate electrode layer 160 and the substrate 101. For example, when a bias voltage of a positive polarity is applied to the gate electrode layer 160, the oxygen vacancy reservoir layer 150 may receive oxygen ions from the resistance change channel layer 110, thereby generating the oxygen vacancies within the resistance change channel layer 110. As another example, when a bias voltage of a negative polarity is applied to the gate electrode layer 160, the oxygen vacancy reservoir layer 150 may provide the oxygen ions to the resistance change channel layer 110, thereby resulting in a decrease in oxygen vacancies in the resistance change channel layer 110.

The gate electrode layer 160 is disposed on the oxygen vacancy reservoir layer 150. The gate electrode layer 160 includes a conductive material. The conductive material may include, for example, doped semiconductor, metal, conductive metal nitride, conductive metal carbide, conductive metal silicide, or conductive metal oxide.

As described above, according to an embodiment of the present disclosure, a semiconductor device includes the substrate, the resistance change channel layer containing oxygen vacancies, the nanodots disposed within the resistance change channel layer and configured to restrain the oxygen vacancies, the source electrode layer and the drain electrode layer disposed at opposite end of the resistance change channel layer, the oxygen vacancy reservoir layer disposed on the resistance change channel layer and exchanging the oxygen vacancies with the resistance change channel layer, and a gate electrode layer disposed on the oxygen vacancy reservoir layer. The nanodots may be disposed or arranged along a thickness direction or a length direction of the resistance change channel layer.

FIGS. 2A-2E schematically illustrate a write operation of a semiconductor device according to an embodiment of the present disclosure. FIGS. 2A-2E may each illustrate changes to a distribution state of oxygen vacancies 115 inside a resistance change channel layer 110 according to a write operation. In the description below, the write operation may be performed by a semiconductor device 1 of FIG. 1. Throughout the write operation explained through FIGS. 2A-2E, the resistance change channel layer 110 of the semiconductor device 1 may have different resistance states that are distinguishable from each other. The write operation of FIGS. 2A-2E may mean a first write operation that increases the conductance value of the resistance change channel layer 110.

Referring to FIG. 2A, an internal structure of a resistance change channel layer 110 is schematically illustrated before the write operation is performed. Nanodots 120 are arranged to form a first row L1 and a second row L2 along a thickness direction of the resistance change channel layer 110, that is, the z-direction. The nanodots 120 are arranged along the x-direction from a region of the resistance change channel layer 110 that is adjacent to a source electrode layer 130 to a region of the resistance change channel layer 110 that is adjacent to a drain electrode layer 140. Before the write operation is performed, the resistance change channel layer 110 of the semiconductor device 1 of FIG. 2A may be in a state of high resistance state.

Referring to FIG. 2B, a write operation is performed by applying a write voltage between a substrate 101 and a gate electrode layer 160. For example, a bias voltage of a positive polarity may be applied to the gate electrode layer 160 while the substrate 101 is grounded. An electric field is formed between the substrate 101 and the gate electrode layer 160 by the write voltage. Under the electric field, oxygen ions move from the resistance change channel layer 110 to an oxygen vacancy reservoir layer 150, and oxygen vacancies 115 are generated in a region of the resistance change channel layer 110 adjacent to the oxygen vacancy reservoir layer 150. Therefore, the concentration of the oxygen vacancies 115 in the region of the resistance change channel layer 110 adjacent to the oxygen vacancy reservoir layer 150 may increase.

The generated oxygen vacancies 115, having positive charges, may drift or move along the electric field within the resistance change channel layer 110 while the write voltage is applied. After the write voltage is removed (e.g., after the electric field is removed), the oxygen vacancies 115 may diffuse along the oxygen vacancy concentration gradient formed in the resistance change channel layer 110. For example, the oxygen vacancies 115 may diffuse from the region adjacent to the oxygen vacancy reservoir layer 150 into the region adjacent to the substrate 101. During the drift or diffusion of the oxygen vacancies 115, the oxygen vacancies 115 may be restrained by the nanodots 120 and may be distributed around the nanodots 120. Because the nanodots 120 inhibit the drift or diffusion of the oxygen vacancies 115, the drift or diffusion may cease more quickly than in the resistance change channel layer 110 without the nanodots 120.

Referring to FIG. 2B, by the write operation, the oxygen vacancies 115 are generated in the resistance change channel layer 110, and thus a conductance value of the resistance change channel layer 110 can be increased. The resistance change channel layer 110 of FIG. 2B may have a first low resistance state that is a resistance state lower than that of the high resistance state of FIG. 2A.

Referring to FIG. 2C, a write voltage greater than the write voltage applied during the write operation of FIG. 2B is applied to the semiconductor device 1. For example, when a pulse voltage is applied as the write voltage, a magnitude of the write voltage may be increased by increasing a period of the pulse voltage or increasing the number of times the pulse voltage is applied. As another example, the magnitude of the write voltage may be increased by increasing the voltage amplitude of the applied write voltage.

The greater magnitude of the applied write voltage in FIG. 2C results in a greater concentration of the oxygen vacancies 115 in the resistance change channel layer 110 compared to the concentration of the oxygen vacancies 115 in FIG. 2B. When the amount of the generated oxygen vacancies 115 increases, the oxygen vacancies 115 may physically connect two or more nanodots 120. Referring to FIG. 2C, the oxygen vacancies 115 may be interconnected via the nanodots 120 of the first row L1. The oxygen vacancies 115 in the first row L1 may form a first conductive channel CH1 within the resistance change channel layer 110 that connects the source electrode layer 130 and the drain electrode layer 140 to each other.

Referring to FIG. 2C, the first conductive channel CH1 is formed along the nanodots 120 of the first row L1. The conductance value of the resistance change channel layer 110 may be higher than the conductance value of the resistance change channel layer 110 of FIG. 2B because of the first conductive channel CH1 generated within the resistance change channel layer 110. The resistance change channel layer 110 of FIG. 2C may have a second low resistance state, which is lower than the first low resistance state of the resistance change channel layer 110 of FIG. 2B.

Referring to FIG. 2D, a write voltage greater than the write voltage applied during the write operation of FIG. 2C is applied. With the greater magnitude of the applied write voltage in FIG. 2D, the concentration of oxygen vacancies 115 generated within the resistance change channel layer 110 may be greater than the concentration of oxygen vacancies 115 of FIG. 2C. Accordingly, the amount of oxygen vacancies 115 conducting and diffusing in the z-direction towards the substrate 101 within the resistance change channel layer 110 may be increased.

The oxygen vacancies 115 may be interconnected via the nanodots 120 in the first row L1 and in the second row L2. The oxygen vacancies 115 additionally form a second conductive channel CH2 that connects the source electrode layer 130 and the drain electrode layer 140 within the resistance change channel layer 110.

Referring to FIG. 2D, the second conductive channel CH2 is formed along the nanodots 120 of the second row L2. The first conductive channel CH1 and the second conductive channel CH2 are respectively disposed within the resistance change channel layer 110. The first conductive channel CH1 and the second conductive channel CH2 are disposed separately from each other. That is, the first conductive channel CH1 and the second conductive channel CH2 are spaced apart from each other in the z-direction. In FIG. 2D, due to the additionally generated second conductive channel CH2, the conductance value of the resistance change channel layer 110 may be greater than the conductance value of the resistance change channel layer 110 of FIG. 2C. The resistance change channel layer 110 of FIG. 2D may have a third low resistance state that is a lower resistance state than the second low resistance state of the resistance change channel layer 110 of FIG. 2C.

Referring to FIG. 2E, a write voltage greater than the write voltage applied during the write operation of FIG. 2D is applied. As the magnitude of the applied write voltage is increased in FIG. 2E, the concentration of oxygen vacancies 115 generated within the resistance change channel layer 110 may be increased compared to the concentration of oxygen vacancies 115 of FIG. 2D. As described above, because the nanodots 120 inhibit the drift or diffusion of the oxygen vacancies 115, the oxygen vacancies 115 are distributed around the nanodots 120 and the first and second conductive channels CH1 and CH2. The oxygen vacancies 115 are distributed to connect the first conductive channel CH1 and the second conductive channel CH2 to each other. When the first conductive channel CH1 and the second conductive channel CH2 are connected to each other, the conductance value of the resistance change channel layer 110 may be increased to a value that is more than the conductance value of the resistance change channel layer 110 of FIG. 2D. The resistance change channel layer 110 of FIG. 2E may have a fourth low resistance state that is a lower resistance state than the third low resistance state of the resistance change channel layer 110 of FIG. 2D.

As described above, because the nanodots 120 restrain the oxygen vacancies 115 within the resistance change channel layer 110, the drift or diffusion of the oxygen vacancies 115 can be inhibited. As a result, when the write operation is performed, the amount of time needed for stabilizing the distribution of the oxygen vacancies 115 in the resistance change channel layer 110 can be reduced. Accordingly, compared to a semiconductor device in which nanodots are not distributed within the resistance change channel layer, in embodiments of the present disclosure, the resistance change channel layer 110 can reach a stable resistance state within a relatively short amount of time. That is, the semiconductor device 1 according to an embodiment of the present disclosure can have a relatively faster operating speed.

In another aspect, the nanodots 120 function as quantum wells that trap electrons within the resistance change channel layer 110. When an electric field is applied to the resistance change channel layer 110, and the electrons conduct in a conduction band of the resistance change channel layer 110, the electrons are trapped in nanodots 120 having an energy level lower than the energy level of the conduction band. When energy exceeding a critical level is provided from outside, the trapped electrons are released from the nanodots 120 by means of tunneling, hopping, thermal excitation, etc., and conduct to other nanodots.

According to an embodiment of the present disclosure, when the oxygen vacancies 115 are interconnected via the nanodots 120, the electrons can efficiently conduct along the oxygen vacancies 115 rather than conducting between the nanodots 120 by the tunneling, hopping, thermal excitation, etc. As described above, when the oxygen vacancies 115 form the conductive channels CH1 and CH2 between the source electrode layer 130 and the drain electrode layer 140, electrons can conduct relatively easily along the conductive channels CH1 and CH2, which are continuous electrical paths. In this case, the nanodots 120 restrain the oxygen vacancies 115 to help the conductive channels CH1 and CH2 to align between the source electrode layer 130 and the drain electrode layer 140. As described above, the first write operation to increase the conductance value of the resistance change channel layer 110 has been explained using FIGS. 2A-2E.

In another embodiment of the present disclosure, a second write operation to reduce the conductance value of the resistance change channel layer 110 may also be performed in substantially the same manner as the first write operation. The second write operation may be performed by applying a write voltage of a polarity opposite to that of the write voltage in the first write operation of FIGS. 2A-2E between the substrate 101 and the gate electrode layer 160 of the semiconductor device 1 in FIG. 1. For example, a bias voltage of a negative polarity may be applied to the gate electrode layer while the substrate 101 is grounded. Under the applied bias voltage, oxygen ions may move from the oxygen vacancy reservoir layer 150 to the resistance change channel layer 110, and the oxygen ions may result in fewer the oxygen vacancies 115 inside the resistance change channel layer 110.

As the magnitude of the write voltage applied during the second write operation increases, the concentration of oxygen vacancies 115 of the resistance change channel layer 110 decreases. Depending on the magnitude of the write voltage applied during the second write operation, the degree to which the conductance value of the resistance change channel layer 110 is decreased may be determined. As a result, the resistance change channel layer 110 may have a plurality of resistance states that are measurably distinct from each other.

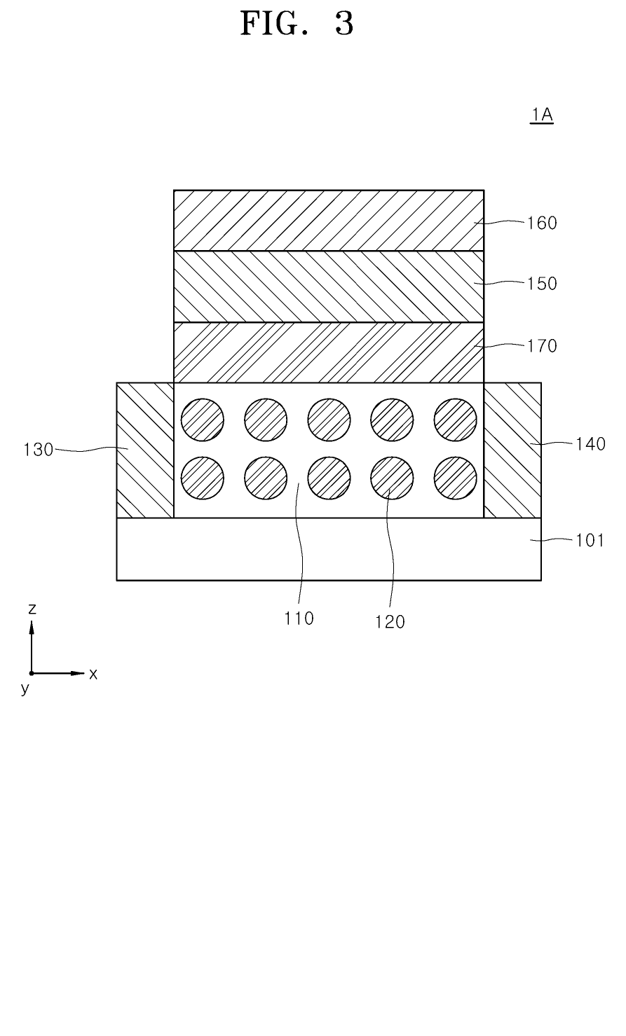

FIG. 3 schematically illustrates a semiconductor device according to an embodiment of the present disclosure. Referring to FIG. 3, a semiconductor device 1A further includes an electrolyte layer 170, as compared to a semiconductor device 1 described with reference to FIG. 1. The same reference numerals as in FIG. 1 denote the same elements.

The electrolyte layer 170 is disposed between a resistance change channel layer 110 and an oxygen vacancy reservoir layer 150. The electrolyte layer 170 includes a material capable of passing oxygen in the form of ions. The electrolyte layer 170 may include, for example, yttria-stabilized zirconia (ZrO₂-Y₂O₃), hafnium yttria (HfO₂-Y₂O₃), gadolinium-doped ceria (CeO₂-Gd₂O₃), lanium strontium manganese oxide, lanium strontium cobalt oxide, or a combination of two or more thereof.

When the write operation is performed, an electric field is formed by a write voltage applied between a gate electrode layer 160 and a substrate 101. Along the electric field, oxygen ions pass through the electrolyte layer 170 and drift between the resistance change channel layer 110 and the oxygen vacancy reservoir layer 150. When the write voltage is removed however, it becomes difficult for oxygen to maintain the form of an ion that can pass through the electrolyte layer 170. Thus, after the write operation is completed, the electrolyte layer 170 suppresses the movement of the oxygen through the electrolyte layer 170 to stably maintain the concentration of oxygen vacancies inside the resistance change channel layer 110.

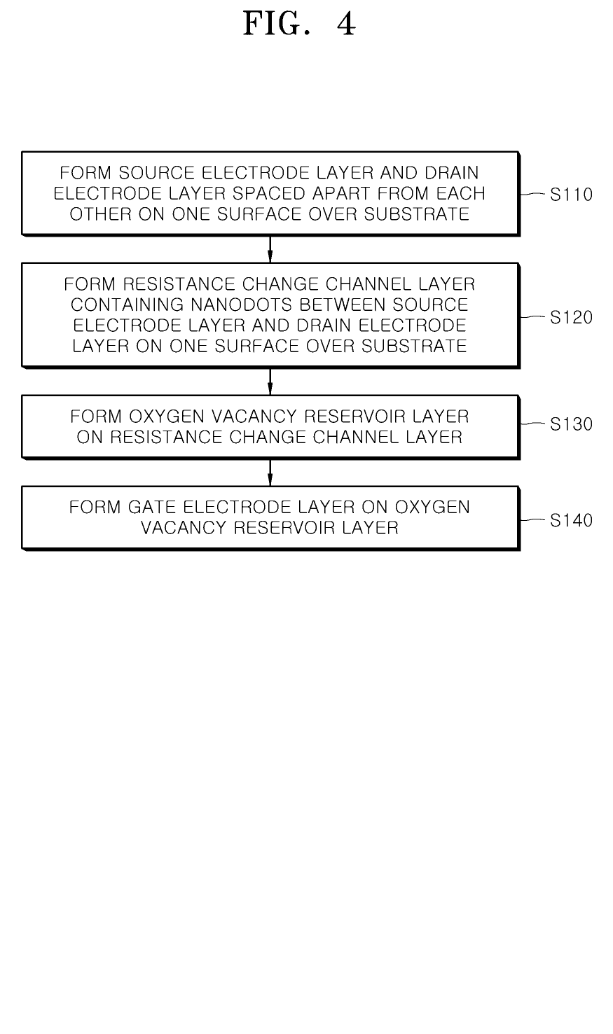

FIG. 4 is a flow chart schematically illustrating a method of manufacturing a semiconductor device according to an embodiment of the present disclosure. The method of manufacturing the semiconductor device following the flow chart of FIG. 4 can be applied to the manufacturing of a semiconductor device 1 of FIG. 1 and a semiconductor device 1A of FIG. 3.

Referring to operation S110 of FIG. 4, a source electrode layer and a drain electrode layer are formed to be spaced apart from each other on one surface over a substrate. In an embodiment, the one surface may be a plane parallel to a surface of the substrate. In an embodiment, the source electrode layer and the drain electrode layer may be arranged to be spaced apart from each other in a lateral direction. Each of the source electrode layer and the drain electrode layer has a form of a conductive pattern.

Referring to operation S120 of FIG. 4, a resistance change channel layer including nanodots is formed between the source electrode layer and the drain electrode layer on the one surface over the substrate. The resistance change channel layer may have a thickness of, for example, 10 nm to 30 nm. In an embodiment, the resistance change channel layer includes metal oxide containing oxygen vacancies. Each of the nanodots may have a size of, for example, 1 nm to 10 nm. The nanodots are uniformly distributed within the resistance change channel layer. The nanodots may be arranged in rows or columns along a thickness direction of the channel change channel layer.

In an embodiment, the resistance change channel layer may be formed by forming a first resistance change material layer on the one surface over the substrate, forming nanoparticles on the first resistance change material layer, and forming a second resistance change material layer on the first resistance change material layer to cover the nanoparticles. At least one of length, width, and height of the nanoparticles may have a size of 1 nm to 10 nm. In another embodiment, the resistance change channel layer may be formed by synthesizing nanoparticles, forming a channel precursor solution, dispersing the nanoparticles into the channel precursor solution to form a channel solution, coating the channel solution on the one surface over the substrate to form a channel coating layer, and heat-treating the channel coating layer.

Referring to operation S130 of FIG. 4, an oxygen vacancy reservoir layer is formed on the resistance change channel layer. The oxygen vacancy reservoir layer includes metal oxide containing oxygen vacancies. Referring to operation S140 of FIG. 4, a gate electrode layer is formed on the oxygen vacancy reservoir layer. The gate electrode layer includes a conductive material.

In some embodiments, an electrolyte layer may be further formed between the oxygen vacancy reservoir layer and the gate electrode layer. The electrolyte layer includes a material through which oxygen can pass in the form of ions.

Through the above-described process, the semiconductor device according to an embodiment of the present disclosure can be manufactured.

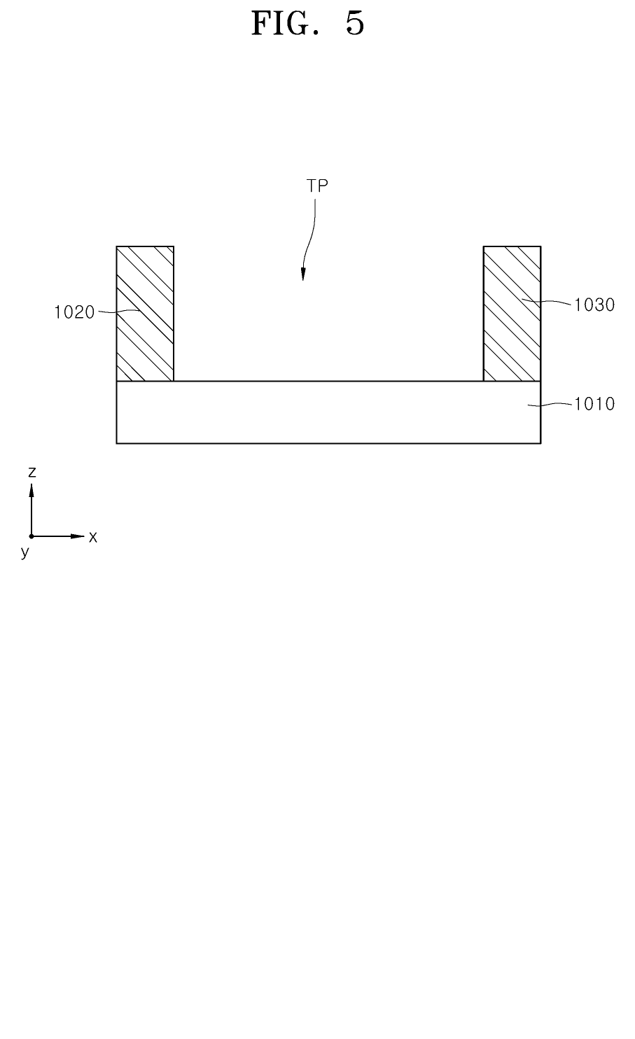

FIGS. 5-10 schematically illustrate a method of manufacturing a semiconductor device according to an embodiment of the present disclosure. The method described with reference to FIGS. 5-10 may be used in operations S110 to S140 of the flow chart of FIG. 4.

Referring to FIG. 5, a substrate 1010 is prepared. The substrate 1010 may include various materials to which a semiconductor integration process is applicable. In an embodiment, the substrate 1010 includes a semiconductor material. The substrate 1010 may be doped with an N-type or P-type dopant to have electrical conductivity.

A source electrode layer 1020 and a drain electrode layer 1030 are formed on the substrate 1010. In an embodiment, the source electrode layer 1020 and the drain electrode layer 1030 may be formed by forming a conductive thin film on the substrate 1010 and patterning the conductive thin film to form a pair of conductive patterns. A trench pattern TP is formed between the source electrode layer 1020 and the drain electrode layer 1030. Each of the source electrode layer 1020 and the drain electrode layer 1030 may include, for example, silicon (Si) doped with an n-type or p-type dopant, tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

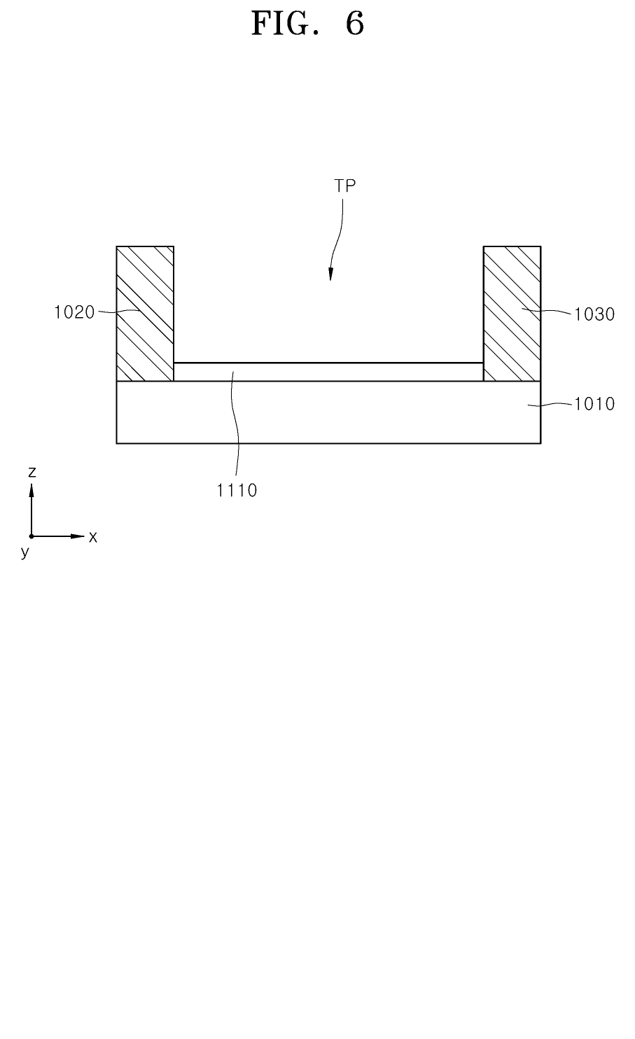

Referring to FIG. 6, a first resistance change material layer 1110 is formed on the substrate 1010 in the trench pattern TP. The first resistance change material layer 1110 includes metal oxide containing oxygen vacancies. The metal oxide may include, for example, tungsten oxide, titanium oxide, molybdenum oxide, selenium oxide, iron oxide, cobalt oxide, vanadium oxide, strontium titanium oxide, yttrium oxide, indium gallium zinc oxide, yttria-stabilized zirconia (ZrO₂-Y₂O₃), hafnium yttria (HfO₂-Y₂O₃), gadolinium-doped ceria (CeO₂-Gd₂O₃), lanium strontium manganese oxide, lanium strontium cobalt oxide, or a combination of two or more thereof.

In an embodiment, a process of forming the first resistance change material layer 1110 may include preparing a sol solution by dissolving a precursor of the metal oxide in a solvent, coating the sol solution on the substrate 1010 by spin coating or dip coating to form a coating layer, and drying the coating layer. In some embodiments, the process of forming the first resistance change material layer 1110 may further include heat-treating the dried coating layer at 200° C. to 900° C. In other embodiments, the process of forming the first resistance change material layer 1110 may include forming a thin film of the metal oxide by using a sputtering method, an atomic layer deposition method, or a chemical vapor deposition method.

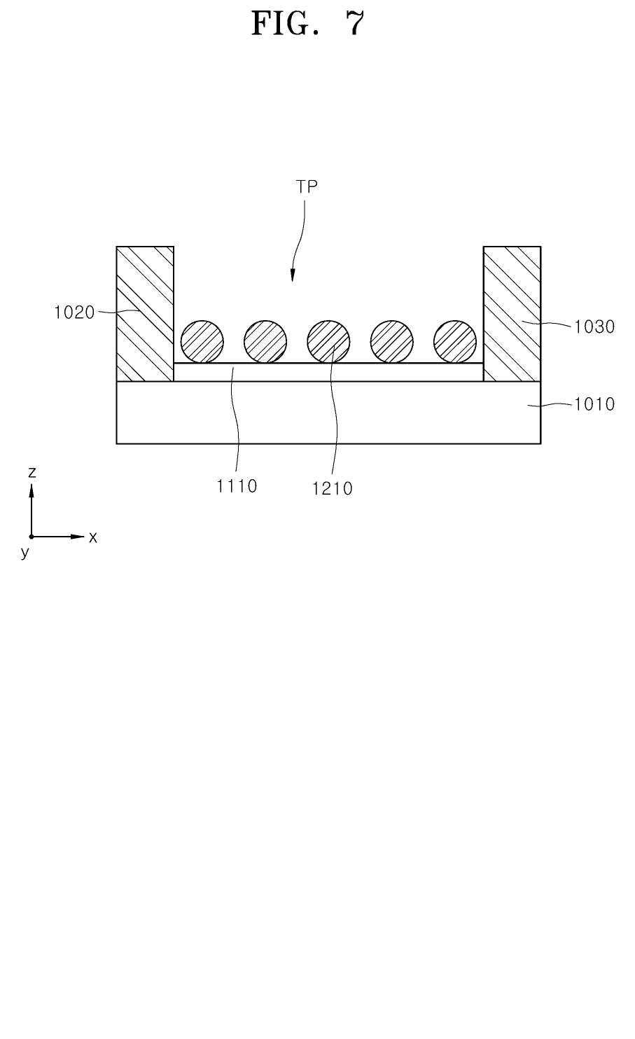

Referring to FIG. 7, first nanodots 1210 are formed on the first resistance change material layer 1110. The first nanodots 1210 are disposed in the trench pattern TP. The process of forming the first nanodots 1210 may include forming nanoparticles on the first resistance change material layer 1110 by performing, for example, at least one process among spin coating, sputtering, atomic layer deposition, and chemical vapor deposition. At least one of length, width, and height of the nanoparticle may have a size of 1 nm to 10 nm.

The first nanodots 1210 may include, for example, gold (Au), silver (Ag), copper (Cu), palladium (Pd), platinum (Pt), nickel (Ni), zinc oxide, titanium oxide, tin oxide, iron oxide, copper oxide, aluminum oxide, cadmium sulfide (CdS), cadmium selenide (CdSe), cadmium telluride (CdTe), lead sulfide (PbS), lead selenide (PbSe), lead telluride (PbTe), tin sulfide (SnS), tin selenide (SnSe), graphene oxide, lead cesium chloride (CsPbCl₃), lead cesium bromide (CsPbBr₃), silver cesium chloride (CsAgCl₂), silver cesium bromide (CsAgBr₂), or a combination of two or more thereof.

In an embodiment, a process of forming the first nanodots 1210 on the first resistance change material layer 1110 may include dispersing the pre-synthesized nanoparticles in a sol solution, spin-coating the sol solution on the first resistance change material layer 1110 to form a thin film including the nanoparticles, and heat-treating the thin film to fix the nanoparticles on the first resistance change material layer 1110. The heat-treating may be performed, for example, at 300 °C. to 600 °C. The nanoparticles may be synthesized by dissolving a particle precursor such as gold chloride (AuCl₃), silver nitrate (AgNO₃), copper sulfide (CuSO₄) in a solvent, and then reacting the metal precursor with a reducing agent such as sodium borohydroxide (NaBH₄) or hydrazine (N₂H₂).

In another embodiment, a process of forming the nanoparticles on the first resistance change material layer 1110 may include depositing a nano-thin film including a material such as gold (Au), silver (Ag), cadmium selenide (CdSe), or lead sulfide (PbS) by a sputtering method, and performing a post-heat treatment on the nano-thin film to convert the nano-thin film into the nanoparticles. As an example, the nano-thin film may have a thickness of 1 to 10 nm. The post-heat treatment may be performed, for example, at 300 °C. to 900 °C.

In another embodiment, the process of forming the nanoparticles on the first resistance change material layer 1110 may include preparing a precursor including a material such as gold (Au), silver (Ag), copper (Cu), platinum (Pt), palladium (Pd), and decomposing the precursor through chemical vapor deposition or atomic layer deposition to form the nanoparticles on the resistance change material layer 1110. Thereafter, optionally, a post-heat treatment may be performed, for example, at 300 °C. to 900 °C.

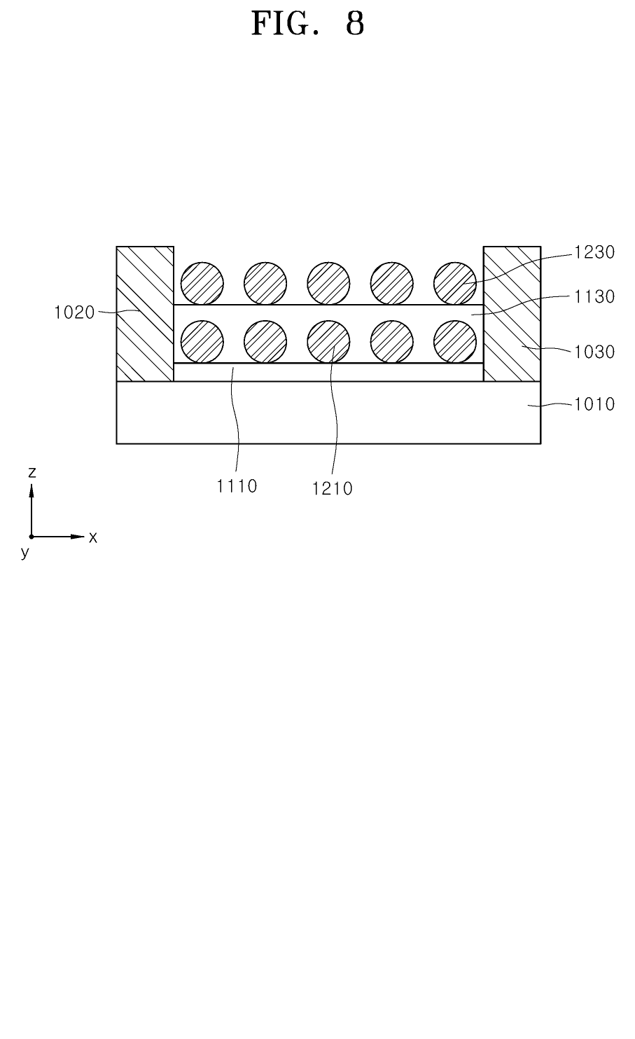

Referring to FIG. 8, a second resistance change material layer 1130 is formed on the first resistance change material layer 1110 to cover the first nanodots 1210. The second resistance change material layer 1130 is formed within the trench pattern TP. The material properties and forming method of the second resistance change material layer 1130 may be substantially the same as the material properties and forming method of the first resistance change material layer 1110.

Second nanodots 1230 are formed on the second resistance change material layer 1130. The second nanodots 1230 are disposed within the trench pattern TP. The configuration and forming method of the second nanodots 1230 may be substantially the same as the configuration and forming method of the first nanodots 1210.

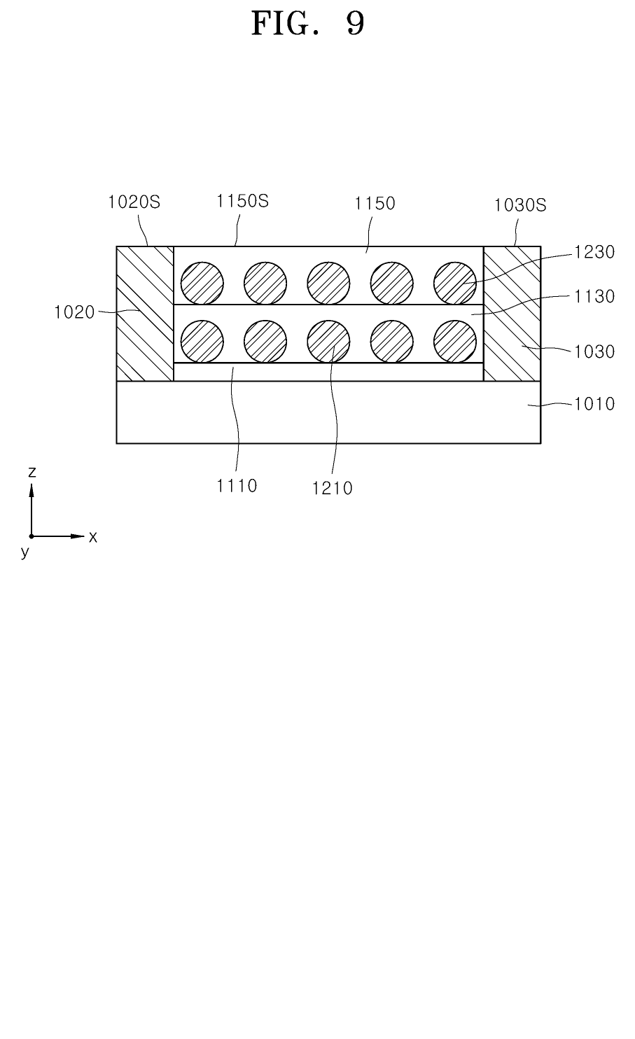

Referring to FIG. 9, a third resistance change material layer 1150 is formed on the second resistance change material layer 1130 to cover the second nanodots 1230. An upper surface 1150S of the third resistance change material layer 1150 may be positioned at substantially the same level as an upper surface 1020S of the source electrode layer 1020 and an upper surface 1030S of the drain electrode layer 1030. The configuration and forming method of the third resistance change material layer 1150 may be substantially the same as the configurations and forming methods of the first resistance change material layer 1110 and the second resistance change material layers 1130.

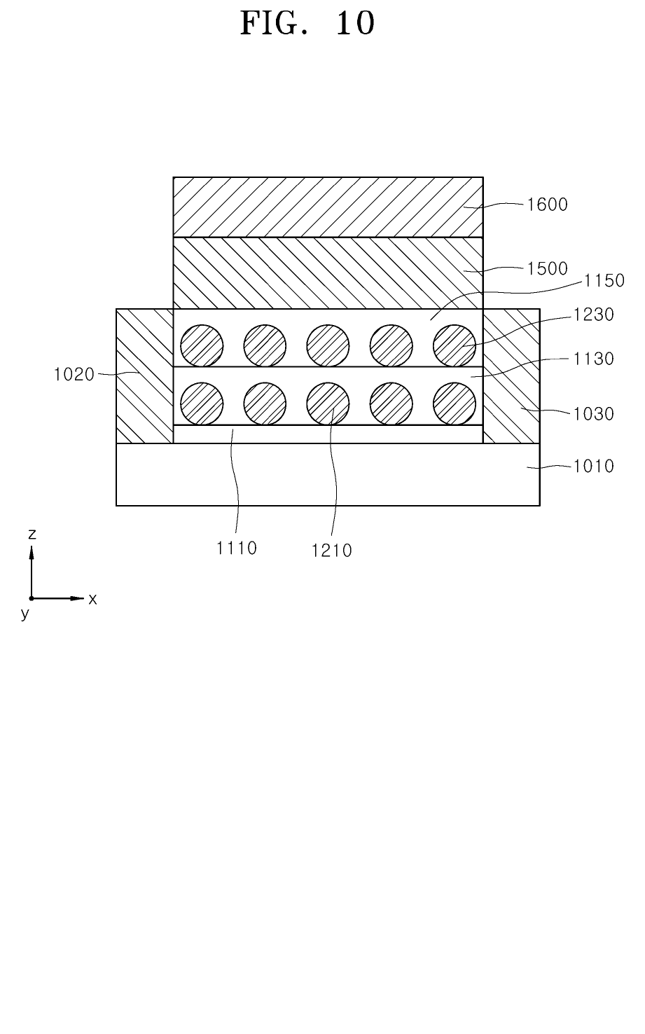

Referring to FIG. 10, an oxygen vacancy reservoir layer 1500 is formed on the third resistance change material layer 1150. The oxygen vacancy reservoir layer 1500 includes metal oxide containing oxygen vacancies. The metal oxide may include, for example, gadolinium oxide, molybdenum oxide, tungsten oxide, copper oxide, titanium oxide, cerium oxide, yttria-stabilized zirconia (ZrO₂-Y₂O₃), gadolinium-doped ceria (CeO₂-Gd₂O₃), scandia-stabilized zirconia (ScSZ), lanthanum strontium cobalt oxide, barium strontium cobalt iron oxide, praseodymium nickel oxide, neodymium nickel oxide, lanthanum nickel oxide, or a combination of two or more thereof. The oxygen vacancy reservoir layer 1500 may be formed using, for example, a chemical vapor deposition method, an atomic layer deposition method, or the like.

A gate electrode layer 1600 is formed on the oxygen vacancy reservoir layer 1500. The gate electrode layer 1600 includes a conductive material. The conductive material may include, for example, doped semiconductor, metal, conductive metal nitride, conductive metal carbide, conductive metal silicide, or conductive metal oxide. The gate electrode layer 1600 may be formed by, for example, a chemical vapor deposition method, an atomic layer deposition method, or the like.

Through the above-described method, a semiconductor device according to an embodiment of the present disclosure can be manufactured. Although FIGS. 6-9 illustrate a method of forming two rows of nanodots, that is, the first nanodots 1210 and the second nanodots 1230, and three layers of resistance change material layers, that is, the first resistance change material layer 1110, the second resistance change material layer 1130, and the third resistance change material layer 1150, the present disclosure is not necessarily limited thereto. In other embodiments, more than three layers of resistance change material layers can be formed, and more than two rows of nanodots can be formed between the more than three layers of resistance change material layers.

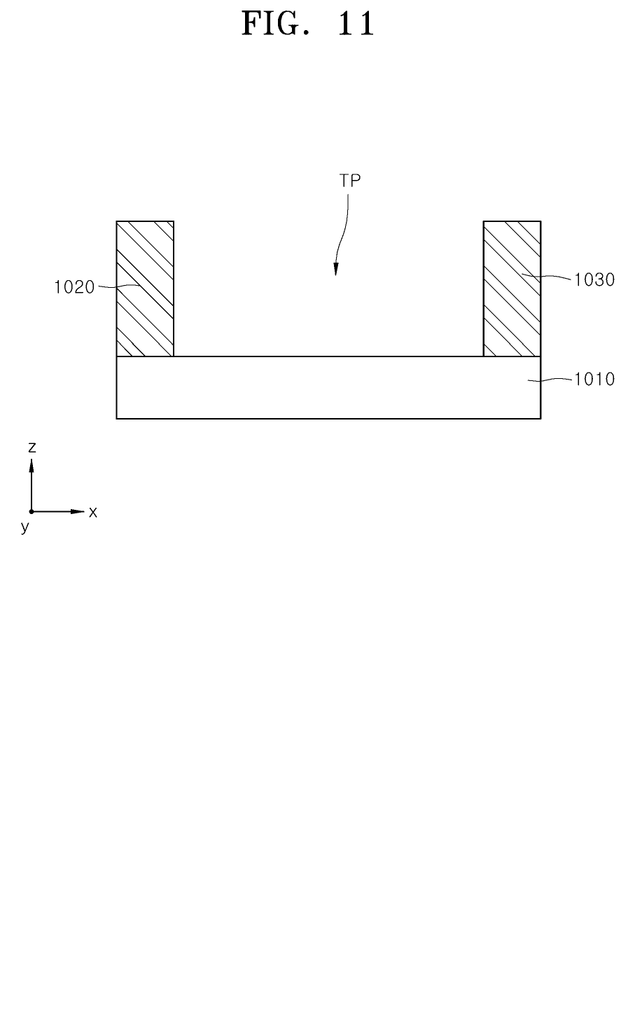

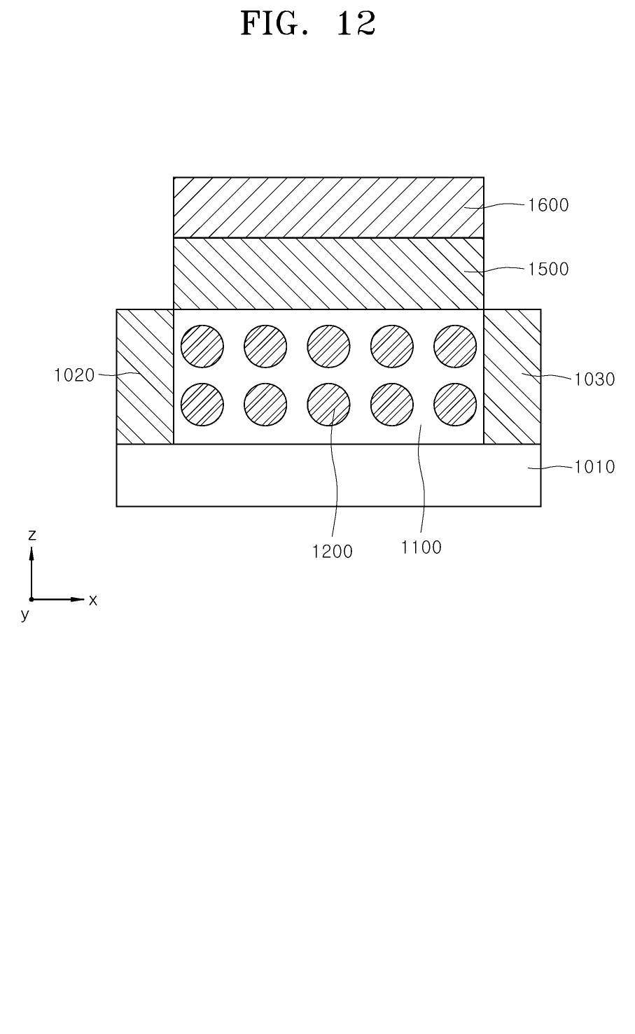

FIGS. 11 and 12 schematically illustrate a method of manufacturing a semiconductor device according to an embodiment of the present disclosure. The method described with reference to FIGS. 11 and 12 may be used in operations S110 to S140 of the flow chart of FIG. 4.

Referring to FIG. 11, by performing a process described with reference to FIG. 5, a source electrode layer 1020 and a drain electrode layer 1030 that are spaced apart from each other are formed on a substrate 1010. A trench pattern TP is formed between the source electrode layer 1020 and the drain electrode layer 1030.

Referring to FIG. 12, a resistance change channel layer 1100 including nanodots 1200 is formed in the trench pattern TP on the substrate 1010. The resistance change channel layer 1100 may be formed as follows. Nanoparticles are synthesized using a precursor material of the nanodot 1200. The precursor material may include, for example, gold chloride (AuCl₃), silver nitrate (AgNO₃), copper sulfate (CuSO₄), titanium chloride (TiCl₄), zinc nitrate (Zn(NO₃)), tin chloride (SnCl₄), or a combination of two or more thereof. The method of synthesizing the nanoparticles may include, for example, colloid synthesis, sol-gel synthesis, microemulsion, or a combination of two or more thereof.

A channel precursor solution is formed by mixing a precursor material having resistance change characteristics into a solvent. The precursor material includes a metal oxide precursor. The metal oxide precursor may include, for example, tungsten oxide, titanium oxide, molybdenum oxide, iron oxide, or a combination of two or more thereof. The solvent may include, for example, water, ethanol, isopropanol, and the like.

The synthesized nanoparticles are dispersed in the channel precursor solution to form a channel solution. Through ultrasonic treatment and stirring, the nanoparticles may be uniformly dispersed in the channel precursor solution. The channel solution is coated on the substrate 1010 to form a channel coating layer. The channel coating layer is heat-treated. The heat treatment may be performed at, for example, 300 °C. to 900 °C. Through the above-described process, the resistance change channel layer 1100 including the nanodots 1200 may be formed in the trench pattern TP.

Referring to FIG. 12, an oxygen vacancy reservoir layer 1500 is formed on the resistance change channel layer 1100. A gate electrode layer 1600 is formed on the oxygen vacancy reservoir layer 1500. Each of the oxygen vacancy reservoir layer 1500 and the gate electrode layer 1600 is formed by using, for example, a chemical vapor deposition method or an atomic layer deposition method.

By performing the above-described process with reference to FIGS. 11 and 12, a semiconductor device according to an embodiment of the present disclosure can be manufactured.

Unlike the structures of the semiconductor device 1 of FIG. 1 and the semiconductor device 1A of FIG. 3, in which a channel in the resistance change channel layer is disposed between a source and a drain arranged in a horizontal direction, in some embodiments a channel of the semiconductor device may extend in a vertical direction.

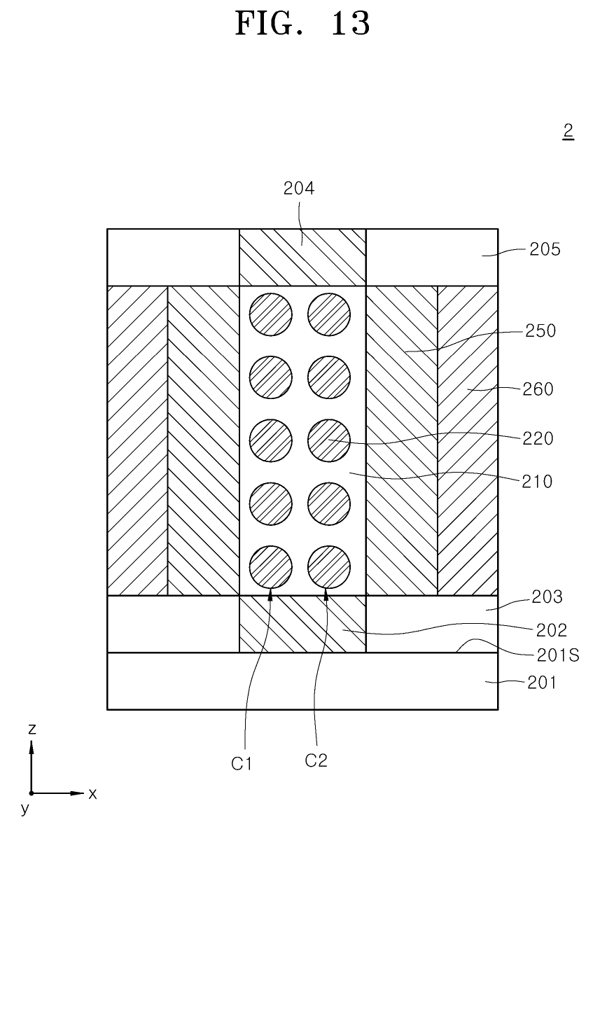

FIG. 13 is a cross-sectional view schematically illustrating a semiconductor device according to an embodiment of the present disclosure. Referring to FIG. 13, compared to a semiconductor device 1 described with reference to FIG. 1 and a semiconductor device 1A described with reference to FIG. 3, a semiconductor device 2 has a different arrangement configuration of a resistance change channel layer 210, a source electrode layer 202, a drain electrode layer 204, an oxygen vacancy reservoir layer 250, and a gate electrode layer 260.

Referring to FIG. 13, a substrate 201 may be substantially the same as a substrate 101 described with reference to FIG. 1. A resistance change channel layer 210 is disposed over the substrate 201 to extend in a first direction perpendicular to a surface 201S of the substrate 201, that is, the z-direction. For example, the resistance change channel layer 210 may have a pillar or pillar-like shape. The characteristics of the material of the resistance change channel layer 210 may be substantially the same as the characteristics of the material of the resistance change channel layer 110 described with reference to FIG. 1. The source electrode layer 202 and the drain electrode layer 204 are disposed spaced apart from each other in the first direction, that is, the z-direction. The source electrode layer 202 and the drain electrode layer 204 are respectively disposed at opposite ends of the resistance change channel layer 210.

Nanodots 220 are disposed along a thickness direction of the resistance change channel layer 210, that is, x-direction, within the resistance change channel layer 210. The nanodots 220 are arranged to form a first column C1 and a second column C2 along the x-direction. The properties of the material of the nanodots 220 may be substantially the same as the properties of the material of the nanodots 120 described with reference to FIG. 1.

Referring to FIG. 13, the source electrode layer 202 is disposed on the substrate 201. A first insulation layer 203 is disposed on the substrate 201 to surround the source electrode layer 202 in a lateral direction. The resistance change channel layer 210 is disposed on the source electrode layer 202.

The oxygen vacancy reservoir layer 250 is disposed on the first insulation layer 203 to be adjacent to the resistance change channel layer 210 in a second direction, for example, the x-direction or y-direction, and perpendicular to the first direction, that is, the z-direction. As an example, the oxygen vacancy reservoir layer 250 may be disposed to surround a pillar-shaped resistance change channel layer 210. As another example, the oxygen vacancy reservoir layer 250 may be disposed to contact a pair of opposing side surfaces of the resistance change channel layer 210. The properties of the material of the oxygen vacancy reservoir layer 250 may be substantially the same as the properties of the material of the oxygen vacancy reservoir layer 150 described with reference to FIG. 1.

The gate electrode layer 260 is disposed on the first insulation layer 203 to be adjacent to the oxygen vacancy reservoir layer 250 in the second direction, for example, the x-direction or the y-direction. As an example, the gate electrode layer 260 may be disposed to surround the oxygen vacancy reservoir layer 250. As another example, the gate electrode layer 260 may be disposed to contact a pair of opposing side surfaces of the oxygen vacancy reservoir layer 250. The properties of the material of the gate electrode layer 260 may be substantially the same as the properties of the material of the gate electrode layer 160 described with reference to FIG. 1.

In some embodiments, a semiconductor device 2 may further include an electrolyte layer (not illustrated) disposed between the resistance change channel layer 210 and the oxygen vacancy reservoir layer 250. The properties of the material of the electrolyte layer may be substantially the same as the properties of the material of the electrolyte layer 170 of the semiconductor device 1A described with reference to FIG. 3.

Referring to FIG. 13, the drain electrode layer 204 is disposed on the resistance change channel layer 210. A second insulation layer 205 is disposed to surround the drain electrode layer 204 in the lateral direction.

A write operation of the semiconductor device 2 may be substantially the same as the write operation of the semiconductor device 1 described above with reference to FIGS. 1 and 2A-2E except for the method of applying a write voltage. In an embodiment, the write operation of the semiconductor device 2 is performed by applying the write voltage between the gate electrode layer 260 and one of the source electrode layer 202 or the drain electrode layer 204.

As described above, each of the semiconductor devices according to various embodiments of the present disclosure includes nanodots arranged within the resistance change channel layer. When oxygen vacancies are generated in the resistance change channel layer by a write operation, the oxygen vacancies may be prevented from moving within the resistance change channel layer by an interaction between the nanodots and the oxygen vacancies. Accordingly, the time needed to stabilize the distribution of the oxygen vacancies during the write operation can be shortened by the presence of nanodots. As a result, the operating speed of the semiconductor device can be improved.

According to an embodiment of the present disclosure, it is possible to control the oxygen vacancies to be distributed near the nanodots. The oxygen vacancies can be physically connected to a plurality of the nanodots to form a conductive channel of electrons. As a result, the magnitude of an operating current that can be secured in the semiconductor device in a low resistance state through the conductive channel can be increased.

The semiconductor devices according to the embodiments of the present disclosure can implement multiple resistance states according to the concentration of the oxygen vacancies. The semiconductor devices can store multiple pieces of information and implement analog data characteristics. Accordingly, the semiconductor devices can be applied to in-memory computing devices. As an example, the semiconductor device can be applied to the neuromorphic computing devices that perform analog operations and artificial intelligence (AI) devices.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not considered a restrictive standpoint. The scope of the present disclosure is not limited to the descriptions, and all distinctive features within an equivalent scope should be construed as included in the present disclosure. All changes within the meaning and range of equivalency of the claims are included within their scope.

What is claimed is:

1. A semiconductor device comprising:
a substrate;
a resistance change channel layer disposed over the substrate and including oxygen vacancies;
nanodots disposed in the resistance change channel layer;
a source electrode layer and a drain electrode layer disposed respectively at opposite ends of the resistance change channel layer;
an oxygen vacancy reservoir layer disposed on the resistance change channel layer and configured to exchange the oxygen vacancies with the resistance change channel layer; and
a gate electrode layer disposed on the oxygen vacancy reservoir layer.

2. The semiconductor device of claim 1, wherein the resistance change channel layer has a conductance value that changes depending on a concentration of the oxygen vacancies.

3. The semiconductor device of claim 1, wherein the nanodots are arranged to form a plurality of rows along a thickness direction of the resistance change channel layer.

4. The semiconductor device of claim 1, wherein the nanodots are arranged along a length direction of the resistance change channel layer between the source electrode layer and the drain electrode layer.

5. The semiconductor device of claim 1, wherein each of the nanodots has a size of 1 nm to 10 nm.

6. The semiconductor device of claim 1, wherein the oxygen vacancies physically connect two or more of the nanodots.

7. The semiconductor device of claim 6, wherein the oxygen vacancies conduct electrons between the source electrode layer and the drain electrode layer based on a voltage applied between the substrate and the gate electrode layer.

8. The semiconductor device of claim 1, wherein each of the nanodots comprises at least one selected from the group consisting of gold (Au), silver (Ag), copper (Cu), palladium (Pd), platinum (Pt), nickel (Ni), zinc oxide, titanium oxide, tin oxide, iron oxide, copper oxide, aluminum oxide, cadmium sulfide (CdS), cadmium selenide (CdSe), cadmium telluride (CdTe), lead sulfide (PbS), lead selenide (PbSe), lead telluride (PbTe), tin sulfide (SnS), tin selenide (SnSe), graphene oxide, lead cesium chloride (CsPbCl₃), lead cesium bromide (CsPbBr₃), silver cesium chloride (CsAgCl₂), and silver cesium bromide (CsAgBr₂).

9. The semiconductor device of claim 1, wherein the resistance change channel layer comprises at least one selected from the group consisting of tungsten oxide, titanium oxide, molybdenum oxide, selenium oxide, iron oxide, cobalt oxide, vanadium oxide, strontium titanium oxide, yttrium oxide, indium gallium zinc oxide, yttria-stabilized zirconia (ZrO₂-Y₂O₃), hafnium yttria (HfO₂-Y₂O₃), gadolinium-doped ceria (CeO₂-Gd₂O₃), lanium strontium manganese oxide, and lanium strontium cobalt oxide.

10. The semiconductor device of claim 1, wherein the oxygen vacancy reservoir layer comprises at least one selected from the group consisting of gadolinium oxide, molybdenum oxide, tungsten oxide, copper oxide, titanium oxide, cerium oxide, yttria-stabilized zirconia (ZrO2-Y₂O₃), gadolinium-doped ceria (CeO₂-Gd₂O₃), scandia-stabilized zirconia (ScSZ), lanthanum strontium cobalt oxide, barium strontium cobalt iron oxide, praseodymium nickel oxide, neodymium nickel oxide, and lanthanum nickel oxide.

11. The semiconductor device of claim 1, further comprising an electrolyte layer that includes oxygen ions and that is disposed between the resistance change channel layer and the oxygen vacancy reservoir layer.

12. The semiconductor device of claim 11, wherein the electrolyte layer comprises at least one selected from the group consisting of yttria-stabilized zirconia (ZrO₂-Y₂O₃), hafnium yttria (HfO₂-Y₂O₃), gadolinium-doped ceria (CeO₂-Gd₂O₃), lanium strontium manganese oxide, and lanium strontium cobalt oxide.

13. A semiconductor device comprising:
a substrate;
a resistance change channel layer including oxygen vacancies, disposed over the substrate and extending in a first direction perpendicular to a surface of the substrate;
a plurality of nanodots disposed to form a plurality of rows in the resistance change channel layer in a thickness direction of the resistance change channel layer;
a source electrode layer and a drain electrode layer disposed respectively at opposite ends of the resistance change channel layer;
an oxygen vacancy reservoir layer disposed adjacent to the resistance change channel layer in a second direction perpendicular to the first direction; and
a gate electrode layer disposed adjacent to the oxygen vacancy reservoir layer in the second direction.

14. The semiconductor device of claim 13, wherein the oxygen vacancies physically connect at least two of the plurality of nanodots in the resistance change channel layer.

15. The semiconductor device of claim 13, further comprising an electrolyte layer disposed between the resistance change channel layer and the oxygen vacancy reservoir layer, wherein oxygen ions are conductive in the electrolyte layer.

16. A method of manufacturing a semiconductor device, the method comprising:
forming a source electrode layer and a drain electrode layer spaced apart from each other on one surface over a substrate;
forming a resistance change channel layer including nanodots between the source electrode layer and the drain electrode layer on the one surface over the substrate;
forming an oxygen vacancy reservoir layer on the resistance change channel layer; and
forming a gate electrode layer on the oxygen vacancy reservoir layer.

17. The method of claim 16, wherein forming the resistance change channel layer comprises:
forming a first resistance change material layer including oxygen vacancies on the one surface over the substrate;
forming nanoparticles on the first resistance change material layer by performing at least one of spin coating, sputtering, atomic layer deposition, and chemical vapor deposition; and
forming a second resistance change material layer including oxygen vacancies on the first resistance change material layer to cover the nanoparticles.

18. The method of claim 16, wherein forming the resistance change channel layer comprises:
performing at least one of colloid synthesis, sol-gel synthesis, and microemulsion on a precursor material of the nanodots to synthesize nanoparticles;
forming a channel precursor solution by mixing a precursor material having resistance change characteristics into a solvent;
dispersing the nanoparticles in the channel precursor solution to form a channel solution;
forming a channel coating layer by coating the channel solution on the one surface over the substrate; and
heat-treating the channel coating layer.

19. The method of claim 16, wherein in forming the resistance change channel layer, the nanodots are disposed to form a plurality of rows along a thickness direction of the resistance change channel layer.

20. The method of claim 16, further comprising forming an electrolyte layer capable of conducting oxygen ions between the oxygen vacancy reservoir layer and the gate electrode layer.
